(19) United States
(12) Patent Application Publication
(10) Pub. No.: US 2012/0186080 A1
(43) Pub. Date: Jul. 26, 2012

(54) CREATING CONDUCTIVIZED TRACES FOR USE IN ELECTRONIC DEVICES

(75) Inventors: Wayne L. Bilodeau, Gorham, ME (US); Craig R. Libby, Gorham, ME (US); Gary P. Blenkhorn, Cape Elizabeth, ME (US)

(73) Assignee: S.D. Warren Company

(21) Appl. No.: 13/014,128

(22) Filed: Jan. 26, 2011

(51) Int. Cl. H05K 3/10

(52) U.S. Cl. 29/846

(57) ABSTRACT

Methods are provided for manufacturing electronic devices such as transistors, solar arrays, optical display arrays, portions of such devices and arrays, and the like. The methods involve providing a substrate having a surface with a pattern of raised portions and recessed portions, adding a conductive material to the surface of the substrate, and manipulating the surface of the substrate to provide the conductive material only in the recessed portions.

### BACKGROUND

A printed circuit board (PCB) is a flat board that is adapted to hold and connect chips and other electronic components. The board is made of layers that interconnect components via conductive pathways. PCBs typically connect mostly discrete components and electronic microcircuits (e.g., chips). Each chip contains from a few thousand up to hundreds of millions of transistors, which are manufactured through a semiconductor fabrication process. This fabrication process is a multiple-step sequence during which electronic circuits are gradually formed on a substrate made of pure semiconducting material. Silicon is the most commonly used semiconductor material today, along with various compound semiconductors. In some cases, the entire fabrication process from start to package-ready chips takes six to eight weeks and is performed in highly specialized and costly facilities. The fixed overhead cost associated with producing chips is generally high. For example, even for simple designs, due to the depreciation of the facilities and equipment, the operation cost could be substantial.

### SUMMARY

Methods and systems are provided for manufacturing electronic devices such as transistors, solar arrays, optical display arrays, portions of such devices and arrays, and the like. The methods include first providing a substrate that has a surface with a pattern of raised portions and recessed portions. Next, a conductive material is added to the surface of the substrate over the pattern of raised portions and recessed portions. Then, after the conductive material has been added, the surface of the substrate is manipulated to provide conductive material only in the recessed portions. One or more additional layers of conductive material can be added to the surface of the substrate and the surface of the substrate can be manipulated to provide the one or more additional layers of conductive material only in the recessed portions (the manipulation of the surface of the substrate can occur after each successive layer or after two or more conductive material layers have been applied).

In one example of the methods, the surface of the substrate has a first surface tension, the conductive material is a curable conductive fluid having a second surface tension that is higher than the first surface tension of the substrate, and manipulating the surface of the substrate includes maintaining the substrate in a position that allows the conductive fluid to flow into the recessed portions of the substrate surface and the curable conductive fluid is cured after it flows into the recessed portions of the substrate surface. In another example of the methods, the conductive material added to the surface of the substrate covers both the raised portions and recessed portions of the surface of the substrate, and manipulating the surface of the substrate to provide the conductive material only in the recessed portions includes removing the raised portions of the surface of the substrate. A further example of the methods includes coating a masking material onto the raised portions of the substrate surface prior to adding the conductive material to the surface of the substrate, and manipulating the surface of the substrate includes removing the conductive material from the masking material on the raised portions of the surface of the substrate.

The details of one or more embodiments of the methods set forth in the claims are set forth in the accompanying drawings and the description. Other features and advantages of the methods set forth in the claims will be apparent from the description and drawings.

### DESCRIPTION OF DRAWINGS

FIG. 1A is an example of a conductivized trace made using the methods described herein.

FIG. 1B is a cross-sectional view of the conductivized trace shown in FIG. 1A.

FIG. 1C is a cross-sectional view of a conductivized trace including an additional layer of curable material at the substrate surface with the pattern of raised portions and recessed portions provided in the surface of the additional layer.

FIG. 2 is an expanded view of a cross-section of a conductivized trace having a first functional layer and a second functional layer in the recessed portion.

FIG. 3A is a cross-sectional view of a conductivized trace in which the raised portions are peaks and the recessed portions are valleys.

FIG. 3B cross-sectional view of a conductivized trace in which the raised portions are raised curves and the recessed portions are recessed curves.

FIG. 4 is a cross-sectional view of a conductivized trace having raised portions and recessed portions like those depicted in FIG. 3A and including an additional layer of curable material at the substrate surface with the pattern of raised portions and recessed portions provided in the surface of the additional layer.

FIG. 5A is a cross-sectional view of a substrate with raised portions and recessed portions on its surface before a conductive material is added.

FIG. 5B is a cross-sectional view of a substrate with raised portions and recessed portions that has had a conductive material added to its surface.

FIG. 5C is a cross-sectional view of a conductivized trace formed by removing the highest portion of the raised portions of the substrate, i.e., removing the portion of the raised portions above line 5C-5C in FIG. 5B.

FIG. 6A is a cross-sectional view of a substrate with raised portions and recessed portions on its surface before masking material or conductive material is added.

FIG. 6B is a cross-sectional view of a substrate with raised portions and recessed portions that has had a masking material added to the surface of the raised portions.

FIG. 6C is a cross-sectional view of a substrate with raised portions and recessed portions on its surface that has had a conductive material added to the surface on top of the masking material.

FIG. 6D is a cross-sectional view of a conductivized trace formed by removing the conductive material and masking material.

FIG. 7A is a cross-sectional view of a substrate with applied masking material and conductive material that is being nipped against an adhesive web.

FIG. 7B is a cross-sectional view of the adhesive web after being nipped against the substrate as shown in FIG. 7A.

FIG. 7C is a cross-sectional view of the conductivized substrate after being nipped against the substrate as shown in FIG. 7A.

FIG. 8 is a diagram showing a process for forming a pattern on the surface of a substrate coating.

FIG. 9A is a magnified view of the surface of a conductive trace showing ink localized in lines representing linear recessed portions in the surface of the textured substrate.

FIG. 9B is a higher power magnification of the surface of the conductive trace shown in FIG. 9A in which a portion of the conductive material has been removed from a recessed area.

FIG. 10 is a magnified view of the surface of a conductive trace that has been subjected to ablation by sanding.

FIG. 11 is a magnified view of the surface of a masked conductive trace in which the metal over the masked areas was removed by an adhesive tape. Like reference symbols in the various drawings indicate like elements.

### DETAILED DESCRIPTION

Methods and systems are described to create conductivized traces for use in electronic devices. The methods include first providing a substrate that has a surface with a pattern of raised portions and recessed portions. A conductive material is added to the surface of the substrate. Then, once the conductive material has been added, the surface of the substrate is manipulated to provide conductive material only in the recessed portions. The conductive material in the recessed portions of the substrate provide conductive traces for use in electronic devices including, but not limited to, lighting, photovoltaics, displays, logic circuits, memory, and passive and active electronic components. As used herein, the term conductive is intended to include conductive and semi-conductive materials. The methods and systems described herein provide for the quick preparation of conductive traces when compared to traditional fabrication processes.

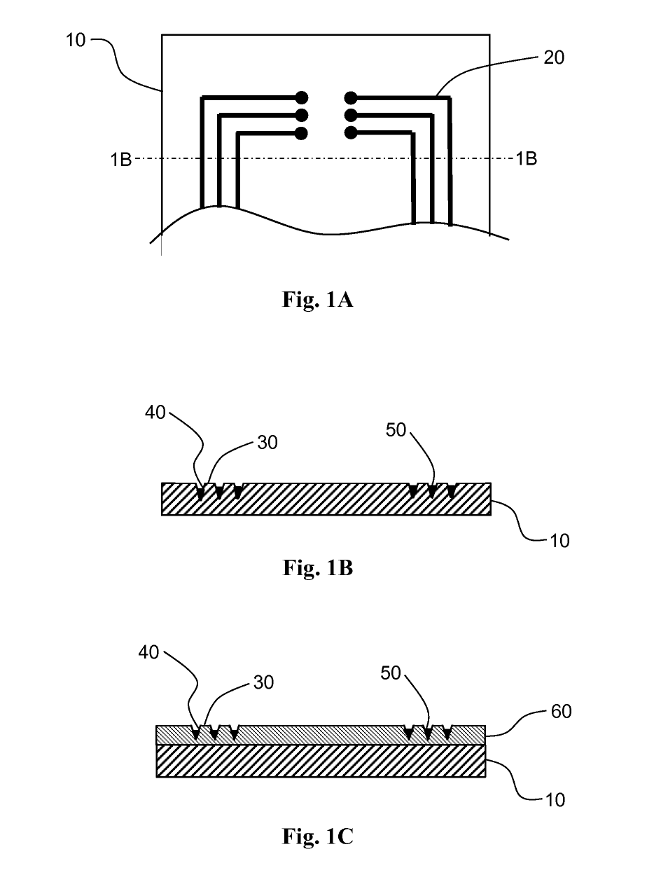

FIGS. 1A and 1B show an example of a conductivized trace made using the methods described herein. FIG. 1A is a top view of a portion of a conductivized trace including a substrate 10 and conductive material in the form of conductive tracings 20 that could be used with a six prong microcircuit chip. FIG. 1B shows a cross-sectional view of the substrate 10 along line 1B-1B in FIG. 1A of the raised portions 30 and recessed portions 40 of the surface of the conductivized trace filled with conductive material 50. The pattern of raised portions and recessed portions can be provided directly in a substrate surface as shown in FIGS. 1A and 1B or, alternatively, the substrate can include an additional layer of curable material at its surface with the pattern of raised portions and recessed portions provided in the surface of the additional layer. FIG. 1C shows a cross-sectional view of a conductivized trace including a substrate 10, an additional layer of curable material 60 at the substrate's 10 surface with the pattern of raised portions 30 and recessed portions 40, with the recessed portions 40 filled with a conductive material 50.

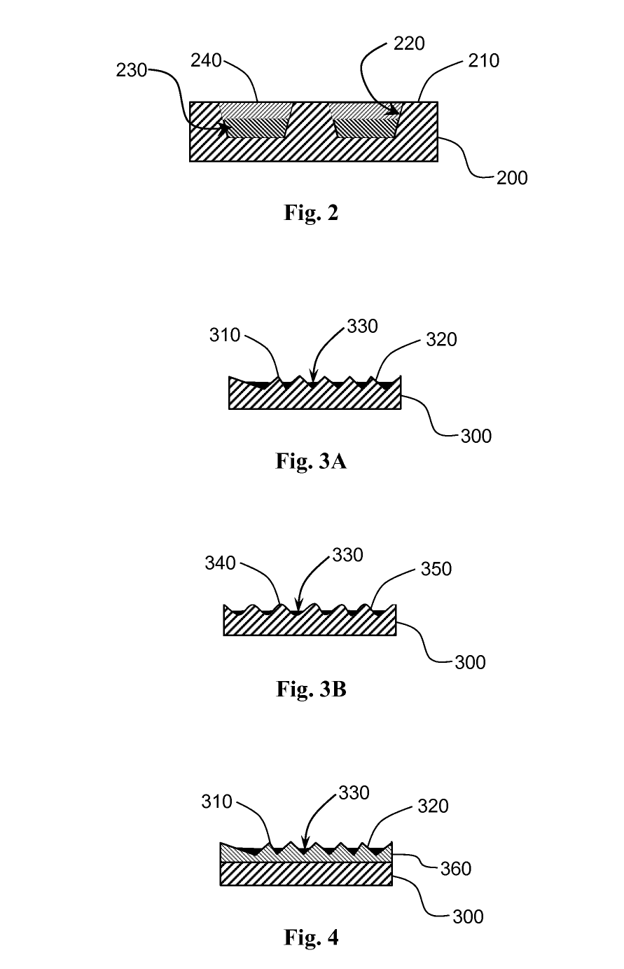

Additionally, the recessed areas of the substrate can provide a reservoir for the deposition of functional materials during a process to make various electronic components that require the sequential placement of more than one functional layer. FIG. 2 shows an expanded view of a cross-section of a conductivized trace 200 including a pattern of raised portions 210 and recessed portions 220, and a first functional layer 230 and as second functional layer 240 within the recessed portions 220. An example of electronic components that utilize multiple functional layers includes batteries in which a galvanic series can be deposited in the recessed areas of a substrate by sequential application of electrolyte layers (e.g., by the printing of fluid carried solid or gel layers). A further example of electronic components that utilize functional layers includes supercapacitors in which printed layers of solid or gel electrolytes can be separated by alternative layers of functional materials such as porous carbon, graphene or carbon-nanotubes. In these embodiments, the texture of the substrate becomes a tool for the fabrication of various active and/or passive electronic components during device formation. The various types of functional materials useful for making electronic components using the methods described herein are well known to those of skill in the art.

In an embodiment of the method described above, the surface of the substrate has a first surface tension and the conductive material is a curable conductive fluid with a second surface tension that is higher than the first surface tension of the substrate. Once the curable conductive fluid is added to the surface of the substrate and the conductive fluid flows into the recessed portions of the substrate surface such that the raised portions of the substrate surface are higher than the highest level of conductive fluid. Then the curable conductive fluid is cured. The result is a conductive trace following the outline of the recessed portions of a substrate. FIGS. 3A and 3B show cross-sectional views of a substrate 300 with peaks 310 and valleys 320 (FIG. 3A) and a substrate 300 with raised curves 340 and recessed curves 350 (FIG. 3B) each forming a conductive trace in which the curable conductive fluid 330 flows down into the recesses due to the differences in surface tension (combinations of raised/recessed curves and peaks/valleys or other shapes that provide relative elevation changes such that a conductive fluid will be directed into lower lying areas of a three-dimensional substrate surface are also useful). Flat areas between the peaks and/or raised portions of the substrate surface are undesirable when using a curable conductive fluid as the curable conductive fluid could collect on the flat areas. As shown in FIG. 4, if an additional layer of curable material 360 is provided on a substrate surface 300, the surface of the additional layer of curable material 360 can have the first surface tension and include a pattern of raised portions and recessed portions such as the peaks 310 and valleys 320 shown in FIG. 3A.

In this embodiment, the curable conductive fluid does not adhere to the raised portions of the substrate surface, but rather collects in the recessed portions. The curable conductive fluid collects in the recessed portions, for example, because the substrate surface has a higher surface energy (i.e., higher surface tension) than the curable conductive fluid. The amount of curable conductive fluid used for a given substrate area is limited to an amount that will allow the raised portions of the substrate surface to extend above the surface of the curable conductive fluid. Low-viscosity, high surface tension fluids are useful. The curable conductive fluid can be an ink, such as a water based ink, solvent based ink, 100% solids fluid thermal, or radiation curable ink. The curable conductive fluid can contain metal or other conductive particles, such as carbon nanotubes, as the conductive component. Examples of suitable curable conductive fluids useful with the methods described herein include METALON® conductive inks from NOVACENTRIX™ (Austin, Tex.).

The conductive fluid can be applied using various methods known to those of skill in the art including, but not limited to, printing, wiping, spreading, spraying, flowing, vacuum metalizing, or sputtering the conductive fluid onto or over the surface. The conductive fluid can be induced to flow into the recessed portions of the substrate surface by gravity or other forces, e.g., forced air or centrifugal forces. Excess curable conductive fluid can be removed, for example, by blowing, scraping, squeegeeing, or drying the fluid off the surface prior to the curable conductive fluid flowing into the recessed portions.

The curable conductive fluid can be cured using various methods known to those of skill in the art including, but not limited to, sintering, forced evaporative drying by air or heat, or activation of a polymerization event. For example, METALON® conductive inks can be cured by sintering using high intensity xenon lamps in the NOVACENTRIX™ PULSEFORGE® line of tools.

Depending on the application, the curable conductive fluid, e.g., ink, used in the methods described herein may have a surface resistivity ranging from 0.1 ohm/sq to about 1.0×10⁹ ohms/sq, preferably 0.15 ohms/sq to 1 ohms/sq.

Additionally, when making electronic components that require the sequential placement of functional layers the recessed areas of the substrate can provide a reservoir for the sequential deposition of functional inks during a printing process, e.g., inkjet printing. For example, the electronic component can be a battery in which a galvanic series is deposited in the recessed areas of a substrate by sequential application of layers of printed electrolytes (e.g., solid or gel layers). A further example includes supercapacitors in which printed layers of solid or gel electrolytes can be separated by alternative layers of functional inks such as porous carbon, graphene or carbon-nanotubes. The types of functional inks described herein are well known to those of skill in the art.

In a further embodiment of the method described above, the conductive material is added to the substrate such that the entire surface, including both the raised portions and the recessed portions of the substrate, are covered. The coverage can be uniform, i.e., one thickness across the surface, or non-uniform, i.e., varying thicknesses across the surface, as long as the desired substrate surface is covered. After the substrate surface if covered, the surface of the substrate is manipulated to provide conductive material only in the recessed portions by removing the highest portion of the raised portions of the substrate. The result is a conductive trace following the outline of the recessed portions of the substrate, e.g., similar to the device shown in FIGS. 1A and 1B. If an additional layer of curable material is provided on the substrate surface, the surface of the additional layer of curable material has the pattern of raised portions and recessed portions, e.g., like the device shown in FIG. 2.

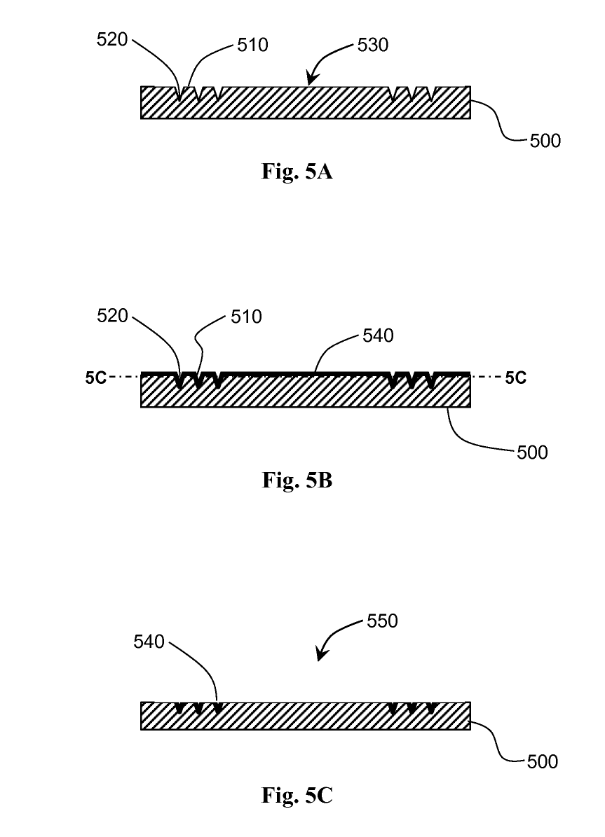

An example of this embodiment of the methods described herein is shown in FIGS. 5A, 5B, and 5C. FIG. 5A shows a cross-section of a substrate 500 with raised portions 510 and recessed portions 520 on its surface 530 before a conductive material is added. FIG. 5B shows a cross-section of the substrate 500 with raised portions 510 and recessed portions 520 that has had a conductive material 540 added to its surface such that both the raised portions 510 and recessed portions 520 are covered. FIG. 5C shows a cross-section of a conductivized trace 550 formed by removing the highest portion of the raised portions 510 of the substrate, i.e., removing the portion of the raised portions above line 5C-5C in FIG. 5B.

Conductive material useful with this embodiment of the methods described herein will be readily apparent to those of skill in the art and can include, but are not limited to, metals, such as silver, copper, or nickel; carbon fibers; carbon nanotubes; graphene; and organic conductors. Application methods for these types of conductive materials are also well known to those of skill in the art and can include, but are not limited to, direct coating, sputtering, powder coating, scrape coating, vacuum metalizing, and printing methods such as ink jet, flexographic, thermal transfer, offset, screen, gravure, and tip printing.

In this embodiment of the methods described herein, the conductive material in the recessed portions is not removed when the highest portion of the raised portions of the substrate and its conductivized coating is removed. The removal of the highest portion of the raised portions of the substrate can be accomplished without disturbing the conductive material in the recessed portions of the substrate. The highest portion of the raised portions of the substrate can be removed by techniques that will be apparent to those of skill in the art including, but not limited to, sanding, buffing, scraping, brushing, polishing, laser ablation, and other controllable surface ablative techniques. Examples include metalizing a substrate surface with silver ink and removing the raised portions of the substrate and its conductivized coating using sanding; vacuum metallizing a substrate surface with aluminum and removing the raised portions of the substrate and its conductivized coating using sanding; and sputter coating a substrate surface with silver and removing the raised portions of the substrate and its conductivized coating using sanding and brushing.

Additionally, this method can be used repeatedly (or used in sequential combination with other methods described herein) when making electronic components that require the sequential placement of functional layers. For example, a two layer component can be made by sputter coating a substrate surface with silver and removing the raised portions of the substrate and its conductivized coating using sanding and brushing then vacuum metallizing the substrate surface with aluminum and removing the raised portions of the substrate and its conductivized coating using sanding.

In an additional embodiment of the method described above, a masking material is coated onto the raised portions of the substrate surface prior to adding the conductive material. After the masking material and conductive material are added, the surface of the substrate is manipulated by removing the masking material from the raised portions of the substrate. The result is a conductive trace following the outline of the recessed portions of the substrate, e.g., similar to the device shown in FIGS. 1A and 1B. If an additional layer of curable material is provided on the substrate surface, the surface of the additional layer of curable material has the pattern of raised portions and recessed portions, e.g., like the device shown in FIG. 2.

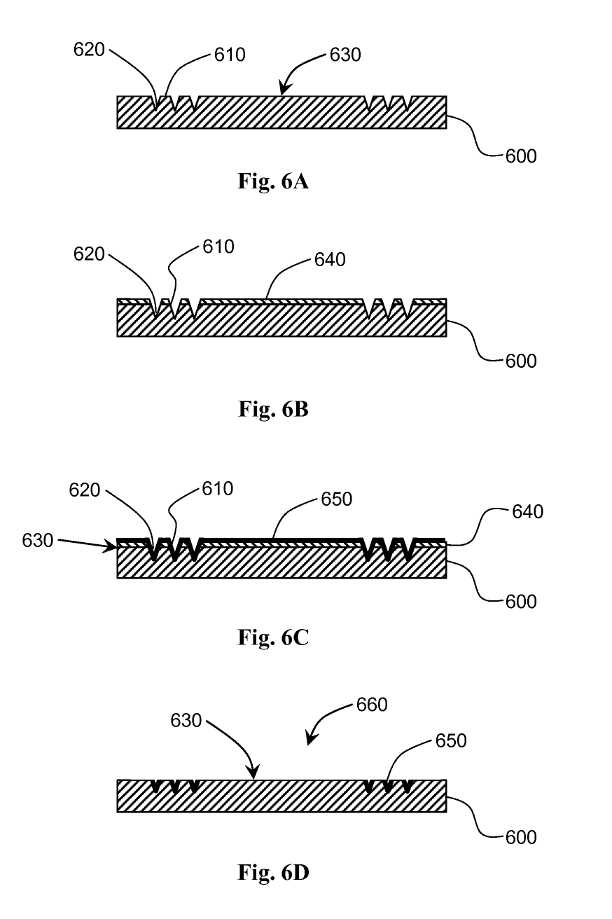

An example of this embodiment of the methods described herein is shown in FIGS. 6A, 6B, 6C, and 6D. FIG. 6A shows a cross-section of a substrate 600 with raised portions 610 and recessed portions 620 on its surface 630 before masking material or conductive material are added. FIG. 6B shows a cross-section of the substrate 600 with raised portions 610 and recessed portions 620 that has had a masking material 640 added to the surface 630 of the raised portions 610. FIG. 6C shows a cross-section of the substrate 600 with raised portions 610 and recessed portions 620 on its surface 630 that has had a conductive material 650 added to the surface on top of the masking material 640 such that both the masking material 640 coated raised portions 610 and uncoated recessed portions 620 are covered by the conductive material 650. FIG. 6D shows a cross-section of a conductivized trace 660 formed on substrate 600 by removing the conductive material 650 and masking material 640 from the surface 630 of the substrate 600. As will be readily apparent to those of skill in the art, depending on the removal operation, the masking material 640 may be removed at the time the conductive material 650 is removed or the masking material 640 can be removed in a subsequent step as needed.

Masking material useful with this embodiment of the methods described herein will be readily apparent to those of skill in the art and can include, but are not limited to, low energy masking agents that have low adhesion to conductive metals such as waxes, silicones, and compounds containing long-chain alkyl groups. One example of a masking material suitable for use with the methods described herein includes TEGO® RC902 radiation curable silicone (Evonik Industries AG; Essen, Germany), wherein the RC902, for example, is tip printed onto the surface of a substrate then cured subsequent to its application. A further example of a masking material suitable for use with the methods described herein includes POLYWAX™ 400 polyethylene microcrystalline wax (Baker Hughes Inc.; Sugarloaf, Tex.), wherein the POLYWAX™ 400, for example, is heated beyond its melting point and tip printed onto the surface of a substrate then allowed to cool.

Masking material can be coated onto the raised portions of the substrate surface using various methods known to those of skill in the art. One example of a method for coating masking material onto the raised portions of the substrate surface includes tip printing. Using tip printing, the masking material is applied to the substrate surface so as to coat only the raised portions, i.e., the protrusion(s) defined by the raised portions of the substrate surface. In this case, the masking material is applied to the upper surface of raised portions of the substrate surface (e.g., using a rotating printing roll). After tip printing, the recessed portions of the substrate surface remain substantially free of the masking material.

Conductive material useful with this embodiment of the methods described herein will be readily apparent to those of skill in the art and can include, but are not limited to, metals, such as silver, copper, or nickel; carbon fibers; carbon nanotubes; graphene; and organic conductors. Application methods for these types of conductive materials are also well known to those of skill in the art and can include, but are not limited to, direct coating, sputtering, powder coating, scrape coating, vacuum metalizing, and printing methods such as ink jet, flexographic, thermal transfer, offset, screen, gravure, and tip printing.

The conductive material overlaying the masking material can be removed by techniques known to those of skill in the art, such as, for example, nipping the coated substrate against an adhesive web such that the conductive material is removed. Examples of adhesive webs suitable for use with the methods described herein include NFPP (rubber based adhesive on Kraft Flatback paper) and NFMBA (rubber based adhesive on PET film) from Nova Films & Foils, Inc. (Bedford, Ohio).

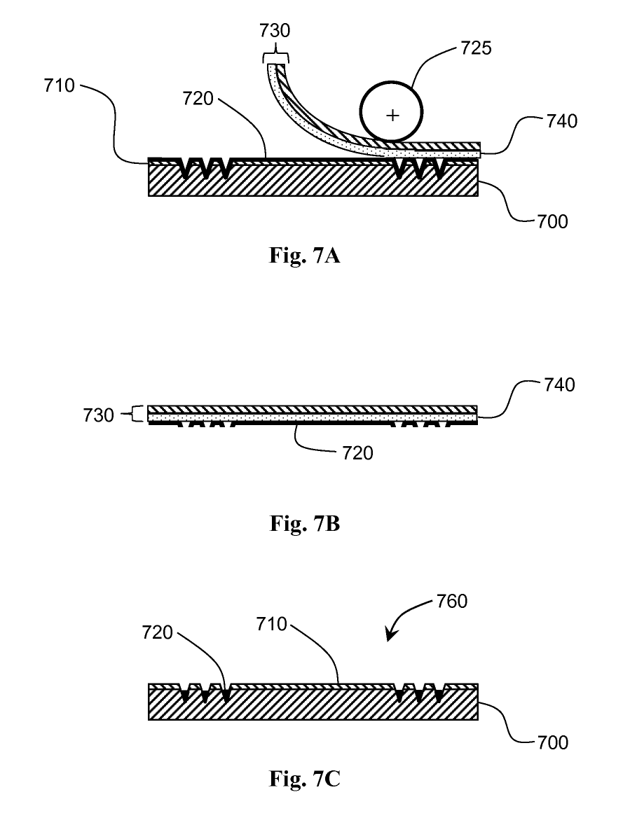

A further application of this embodiment of the methods described herein involves creating a useable conductive trace using the conductive material removed from the raised portions of the substrate, i.e., the conductive material overlaying the masked portion of the substrate surface creates a useable conductive trace on a further substrate when removed. For example, if the masking material and conductive material coated substrate is nipped against an adhesive web, a useful conductive trace is formed on both the substrate and the adhesive web. An example of this further application of this embodiment is shown in FIGS. 7A, 7B, and 7C. FIG. 7A shows a cross-section of a substrate 700 that has an applied masking material 710 and applied conductive material 720 that is being nipped with a roller 725 against an adhesive web 730 with an adhesive coating 740. FIG. 7B shows a cross-section of the resulting separated adhesive web 730 with conductive material 720 and FIG. 7C shows a cross-section of the conductivized substrate trace 760 (the remaining masking material can be removed as needed). Thus, as shown in FIGS. 7A, 7B, and 7C, when the raised portions and recessed portions of the substrate are complementarily designed, both the adhesive web and conductivized substrate trace can form useful conductive traces.

Additionally, this method can be used repeatedly (or used in sequential combination with other methods described herein) when making electronic components that require the sequential placement of functional layers. For example, a two layer component can be made by re-coating a substrate prepared as shown in FIG. 7C (as the mask layer is still present) then removing the conductive material on the making layer with an adhesive web.

Forming Substrates

Substrates useful with the methods described herein are formed by imparting a pattern to a substrate surface using a pattern imparting surface or coating a curable liquid onto a substrate, imparting a pattern to the coating using a pattern imparting surface, curing the coating, and stripping the substrate and the cured coating from the pattern-imparting surface. Methods for forming suitable substrates are provided in U.S. patent application Ser. No. 12/266,795, filed Nov. 7, 2008, which is incorporated herein by reference for its disclosure of forming substrates. One particular example of a process for forming a substrate useful with the methods described herein is conducted on a continuous web of material which is drawn through a series of processing stations (e.g., as shown diagrammatically in FIG. 6).

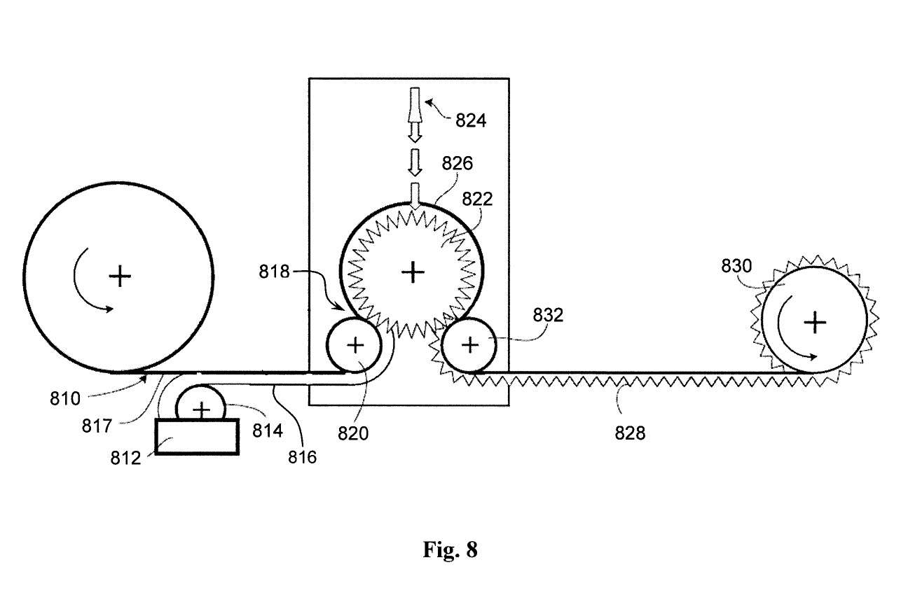

Referring to FIG. 8, a web 810 (e.g., a polymeric film), first passes through a coating station 812 where a coating head 814 applies a wet coating 816 to a surface 817 of the web. Next, the coated web passes through a nip 818 between a backing roll 820 and an engraved roll 822, with the wet coating 816 facing the engraved roll 822. The engraved roll carries a pattern on its surface, the inverse of which is imparted to the wet coating. Nip pressure is generally relatively low (e.g., “kiss” pressure), with the nip pressure being selected based on the viscosity of the coating to prevent the coating from being squeezed off of the web, while still allowing the engraved texture to be imparted to the coating. If the pattern is to be applied directly to the surface of an existing substrate, the same system can be used where the engraved roll simply is nipped against the surface of the substrate that has been prepared by heating or other method to be ready to adopt the pattern of the engraved roll.

For the patterned or coated and patterned web, after leaving the nip, the web passes through a curing station 824 (e.g., an electron beam (e-beam) or UV curing device or a heating device). The coating is cured while it is still in contact with the surface of the engraved roll. E-beam energy or actinic radiation (represented in FIG. 8 by arrows) is generally applied from the back surface 826 of the web and passes through the web and cures the coating 816 to form a cured, textured coating 828 that is firmly adhered to the web 810. The web 810 and cured coating 828 may be stripped off the engraved roll at take-off roll 832. At this point, the web 810 and cured coating 828 can be further processed using the methods discussed above or wound up on a take up roll 830 for later processing using the methods discussed above. If UV curing is used, the web should be transparent or translucent to UV radiation if curing is to be performed from the back surface of the web as shown in FIG. 8.

If a coated web is used, the coating 816 may be applied using any suitable method. Suitable techniques include offset gravure, direct gravure, knife over roll, curtain coating, spraying, and other printing and coating techniques. The coating can be applied directly to the web, before the substrate contacts the engraved roll, as shown in FIG. 8, or alternatively the coating can be applied directly to the engraved roll, in which case the substrate is pressed against the coated engraved roll.

The engraved roll discussed above is one example of a replicative surface disposed on a rotating endless surface such as a roll, drum, or other cylindrical surface that may be used to impart a pattern directly to a substrate or to a coating on a substrate surface. Other types of pattern-imparting devices, including flat replicative surfaces and textured webs, can also be used as a mold to cast a substrate pre-form. U.S. patent application Ser. No. 11/742,257, filed on Apr. 4, 2007, provides examples of such pattern-imparting methods and is incorporated herein by reference for its disclosure of pattern-imparting methods.

The replicative surfaces discussed above provide patterns consistent with the shapes and layouts of desired electronic circuits, printed circuits, electrical arrays, such as solar collector arrays or optical display grid arrays, and the like.

Materials

The substrate may be any desired material, such as a polymer film, sheet, or board, or if a coating is used on the substrate, a paper, film, sheet, foil, board, or glass to which the coating will adhere. Polymeric films or other surfaces to which a coating would not normally adhere can be treated, e.g., by flame treatment, corona discharge, or pre-coating with an adhesion promoter. Examples of substrates suitable for use with the methods described herein include paper, polyester films, films of cellulose triacetate, biaxially oriented polystyrene, and acrylics.

If electron beam or UV curing is used, the coatings preferably include an acrylated oligomer, a monofunctional monomer, and a multifunctional monomer for cross-linking. If ultraviolet radiation is used to cure the acrylic functional coating, the coating will also include a photoinitiator as is well-known to those of skill in the art. Curable conductive fluids may use these ingredients as a binder, to which silver filler or other highly electrically conductive filler is added.

Preferred acrylated oligomers include acrylated urethanes, epoxies, polyesters, acrylics and silicones. The oligomer contributes substantially to the final properties of the coating. Practitioners skilled in the art are aware of how to select the appropriate oligomer(s) to achieve the desired final properties. Desired final properties for the release sheet of the invention typically require an oligomer which provides flexibility and durability. A wide range of acrylated oligomers are commercially available from Cytec Industries Inc. (Woodland Park, N.J.), such as Ebecryl 6700, 4827, 3200, 1701, and 80, and Sartomer USA, LLC (Exton, Pa.), such as CN-120, CN-999 and CN-2920.

Typical monofunctional monomers include acrylic acid, N-vinylpyrrolidone, (ethoxyethoxy) ethyl acrylate, or isodecyl acrylate. Preferably the monofunctional monomer is isodecyl acrylate. The monofunctional monomer acts as a diluent, i.e., lowers the viscosity of the coating and increases flexibility of the coating. Examples of monofunctional monomers include SR-395 and SR-440, available from Sartomer USA, LLC, and Ebecryl 111 and ODA-N (octyl/decyl acrylate), available from Cytec Industries Inc.

Commonly used multifunctional monomers for cross-linking purposes are trimethylolpropane triacrylate (TMPTA), propoxylated glyceryl triacrylate (PGTA), tripropylene glycol diacrylate (TPGDA), and dipropylene glycol diacrylate (DPGDA). Preferably, the multifunctional monomer is selected from a group consisting of TMPTA, TPGDA, and mixtures thereof. The preferred multifunctional monomer acts as a cross-linker and provides the cured layer with solvent resistance. Examples of multifunctional monomers include SR-9020, SR-351, SR-9003 and SR-9209, manufactured by Sartomer USA, LLC, and TMPTA-N, OTA-480 and DPGDA, manufactured by Cytec Industries Inc.

Preferably, the coating comprises, before curing, 20-50% of the acrylated oligomer, 15-35% of the monofunctional monomer, and 20-50% of the multifunctional monomer. The formulation of the coating will depend on the final targeted viscosity and the desired physical properties of the cured coating. In some implementations, the preferred viscosity is 0.2 to 5 Pascal seconds, more preferably, 0.3 to 1 Pascal seconds, measured at room temperature (21-24° C.).

Coating compositions may also include other ingredients, such as opacifying agents, colorants, slip/spread agents and anti-static or anti-abrasive additives. The opacity of the coating may be varied, for example, by the addition of various pigments, such as titanium dioxide, barium sulfate and calcium carbonate, by the addition of hollow or solid glass beads, or by the addition of an incompatible liquid such as water. The degree of opacity can be adjusted by varying the amount of the additive used.

As mentioned above, a photoinitiator or photoinitiator package may be included if the coating is to be UV cured. A suitable photoinitiator is available from the Sartomer USA, LLC under the tradename KTO-46™. The photoinitiator may be included at a level of, for example, 0.5-8%, preferably 1-6%, and more preferably 2-5%.

### EXAMPLES

### Example 1

### Pchem Associates PGI-722-150 Ink

A substrate composition was prepared using the components described in Table 1.

TABLE 1
Substrate Composition for Example 1

| Component | Amount | Descriptor |
|---|---|---|
| Sartomer^{a} SR610 | 30% | oligomer |
| Sartomer SR351 | 10% | tri-functional cross-linker |
| Sartomer SR9003 | 50% | difunctional monomer |
| Sartomer SR395 | 10% | monofunctional diluent (helps |
| | | to lower surface tension) |
| Blue Star Silicones^{b} | 1 part per 100 parts | facilitates removal from |
| Rhodorsil 47V100 | above | master and lowers surface |
| | | tension |
| Lamberti^{c} Esacure | 2 parts per 100 parts | photoinitiator for uv curing |
| KTO 046 | above | |

^{a}Sartomer USA, LLC (Exton, PA)
^{b}Bluestar Silicones USA Corp. (East Brunswick, NJ)
^{c}Lamberti S.p.A. (Gallarate, Italy)

To form a substrate that has a surface with a pattern of raised portions and recessed portions (textured substrate) the substrate composition was cast against a groove master pattern with the following dimensions:

Pitch (P)=0.0155 in. (0.3937 mm)

LPI=64.59

DOC=0.0040 in. (0.1016 mm)

Angle ˜125.7°

The textured substrate was cast by flooding the groove master pattern with the substrate composition and adding DuPont Melinex 617 (500 gauge) polyester film on top of the wet coating (DuPont Teijin Films U.S. Limited Partnership; Hopewell, Va.). A squeegee was used to press and wipe down against the dry side of the film so that excess coating could be metered out and wet coating could effectively wet out the texture of the groove master pattern. The sandwich of the groove master pattern, wet coating, and Melinex 617 was passed under a Fusion UV curing benchtop curing unit (Fusion UV Systems, Inc.; Gaithersburg, Md.). In the Fusion UV curing benchtop curing unit, Fusion 600 watts/in V, H, and D bulbs were used at full power and belt speed of 50 feet per minute. One pass cured the substrate composition between the polyester film and groove master pattern. The polyester film was removed and the cured substrate composition had a negative texture of the groove master pattern replicated on the substrate surface thereby forming the textured substrate.

The textured substrate was coated with Pchem Associates PGI-722-150 aqueous conductive silver nanoparticle ink (Pchem Associates Inc.; Bensalem, Pa.). PGI-722 is a development ink but it and various analogs are available from Pchem Associates. The coating was done with a knife-over-roll simulation by flooding the surface of the textured substrate with the silver nanoparticle ink on one end and dragging the silver nanoparticle ink across the surface of the textured substrate with an edge of a popsicle stick. The “knife” rode along the tops of the raised portions of the textured substrate and removed excess ink such that the ink de-wet off the tops of the raised portions and flowed into the recessed portions. The added silicone in the substrate composition helps to ensure a low surface tension to promote de-wetting of the aqueous silver nanoparticle ink. Coating thickness was approximately 0.076 mm. The ink was thermally cured for 5 minutes at 100° C.

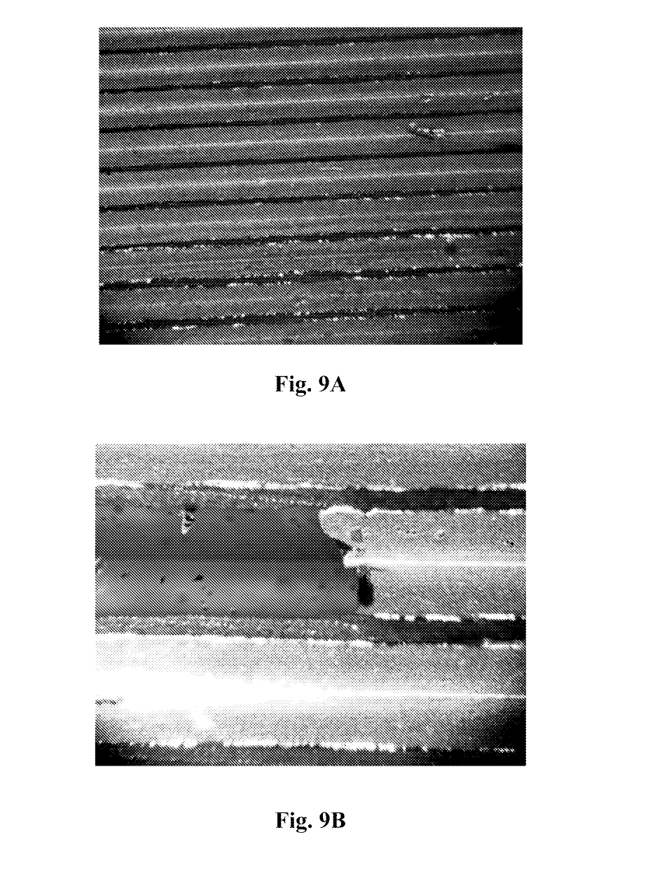

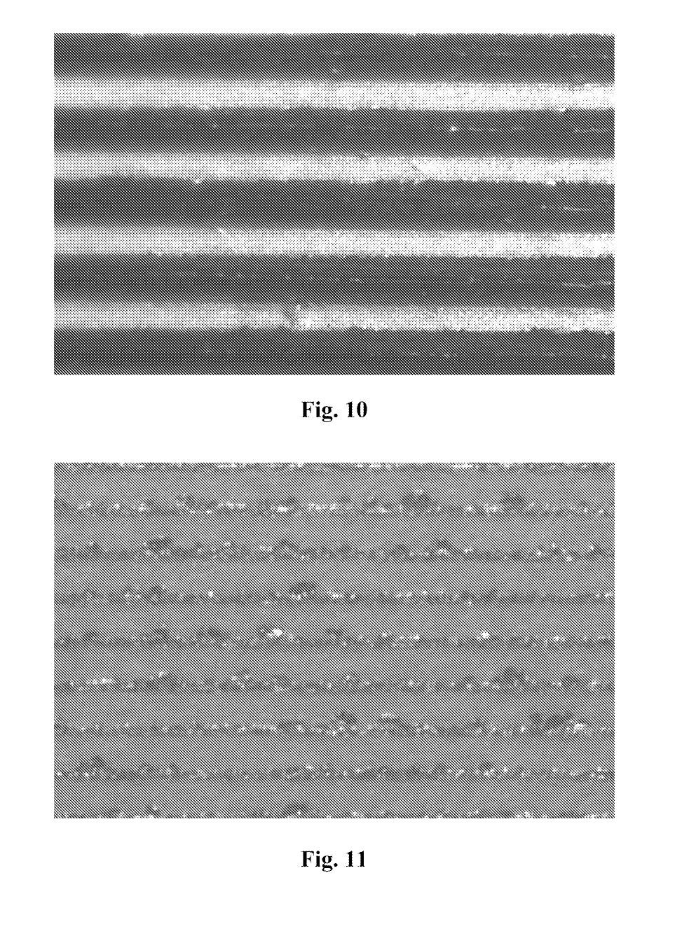

Visual inspection of the conductive trace (see FIG. 9A) showed that the ink de-wetted into the recessed portions (the lighter portions being the conductive material in the recessed portions and the darker lines being uncoated raised portions). Further, FIG. 9B shows a magnified view of a portion of the conductive trace in FIG. 9A in which a portion of the conductive material has been removed from a recessed area (again the lighter portions are conductive material). Additionally, a Fluke 1503 meter (Fluke Corporation; Everett, Wash.) was used to test the conductivity of the formed conductive traces. The conductive traces provided by the textured substrate with silver nanoparticle ink in the recessed portions measured a conductivity of 1.6 ohms which indicates a conductive substrate.

### Example 2

### Surface Removal (Supplemental Ablation of an Ink Coated Surface)

The conductive trace from Example 1 was additionally treated by ablating the surface layer by sanding (using a knife-sharpening stone to simulate commercial sanding equipment) to demonstrate this additional method of treating the surface. FIG. 10 shows the conductive trace after being further treated by surface ablation (the raised portions without conductive material are widened and any portions of conductive material that may have been on the raised portions is removed). In FIG. 10, the light lines are the raised portions that were subjected to surface ablation.

### Example 3

### Surface Removal (Hand Sanding of an Aluminum Metalized Substrate)

A textured substrate formed according to the method of Example 1 was aluminum metalized by Dunmore Corporation (Bristol, Pa.) in a laboratory using a Bell jar setup. The actual metal thickness was unknown but believed to be over 0.001 mm. The sample was hand sanded on the raised portions of the textured substrate using a knife sharpening stone to remove the metal only from the raised portions. The conductive traces formed were tested for conductivity using the Fluke meter as described in Example 1 and the traces showed conductivity.

### Example 4

### Surface Removal (Hand Sanding of an Aluminum Metalized Substrate)

A textured substrate formed according to the method of Example 1 was aluminum metalized by Dunmore Corporation to 0.001 mm using Dunmore's lab Bell jar vacuum metalizing equipment. The sample was hand sanded on the raised portions of the textured substrate using a knife sharpening stone to remove the metal only from the raised portions. The conductive traces formed were tested for conductivity using the Fluke meter as described in Example 1 and the traces showed conductivity.

### Example 5

### Surface Removal (Commercial Sanding of an Aluminum Metalized Substrate)

A textured substrate formed according to the method of Example 1 was aluminum metalized by Dunmore Corporation to 0.001 mm using Dunmore's lab Bell jar vacuum metalizing equipment. Samples of the vacuum metalized textured substrate were sent to Time Savers, Inc. (Maple Grove, Minn.) for sanding using commercial sanding equipment (brush sander with platen). The commercial sanding equipment removed aluminum metal from only the raised portions of the metalized textured substrate thus producing conductive traces. The conductive traces formed were tested for conductivity using the Fluke meter as described in Example 1 and the traces showed conductivity.

### Example 6

### Surface Removal (Hand Sanding of a Sputtered Silver Metalized Substrate)

A textured substrate formed according to the method of Example 1 was sputtered with silver metal by Bekaert Specialty Films, LLC (San Diego, Calif.) to a thickness of 0.00008 mm. The coated textured substrate samples was hand sanded on the raised portions of the textured substrate using a knife sharpening stone to remove the metal only from the raised portions. The silver conductive traces formed were tested for conductivity using the Fluke meter as described in Example 1 and the traces showed conductivity.

### Example 7

### Masking

Two sets of textured substrates formed according to the method of Example 1 were aluminum metalized by Dunmore Corporation to 0.001 mm using Dunmore's lab Bell jar vacuum metalizing equipment. The first set of textured substrates was masked with polyethylene wax and the second set was used as a control and did not have any mask coating on the surface. Both sets of substrates were exposed to Scotch 810 tape (3M; St. Paul, Minn.) to see if the aluminum could be removed. Aluminum was easily removed from the samples that had mask coating (from the masked areas), but was not removed from the samples that did not have any mask coating. FIG. 11 shows the surface of a conductive trace that has had aluminum removed from the masked substrates with Scotch 810 tape (the thinner, rough edged lines are the remaining conductive traces). The tape application was performed at room temperature.

The present claims are not limited in scope by the embodiments disclosed herein which are intended as illustrations of a few aspects of the invention and any embodiments which are functionally equivalent are within the scope of the claims. Various modifications of the methods in addition to those shown and described herein will become apparent to those skilled in the art and are intended to fall within the scope of the claims. Further, while only certain representative combinations of the method steps disclosed herein are specifically discussed in the embodiments above, other combinations of the method steps will become apparent to those skilled in the art and also are intended to fall within the scope of the claims. Thus a combination of steps may be explicitly mentioned herein; however, other combinations of steps are included, even though not explicitly stated. The term “comprising” and variations thereof as used herein is used synonymously with the term “including” and variations thereof and are open, non-limiting terms.

What is claimed is:

1. A method of forming an electronic device comprising:
providing a substrate, the substrate having a surface with a pattern of raised portions and recessed portions;
adding a conductive material to the surface of the substrate; and
manipulating the surface of the substrate to provide the conductive material only in the recessed portions.

2. The method of claim 1, further comprising adding one or more additional layers of conductive materials to the surface of the substrate, wherein the surface of the substrate is manipulated to provide the one or more additional layers of conductive material only in the recessed portions.

3. The method of claim 2, wherein manipulating the surface of the substrate to provide the conductive material only in the recessed portions occurs after each conductive material is applied.

4. The method of claim 2, wherein manipulating the surface of the substrate to provide the conductive material only in the recessed portions occurs after two or more conductive materials are applied.

5. The method of claim 1, wherein the surface of the substrate has a first surface tension, the conductive material is a curable conductive fluid having a second surface tension that is higher than the first surface tension of the substrate, and manipulating the surface of the substrate comprises maintaining the substrate in a position that allows the conductive fluid to flow into the recessed portions of the substrate surface and curing the curable conductive fluid.

6. The method of claim 5, wherein the substrate further comprises a layer of curable material at the substrate surface, the surface of the curable material comprising the pattern of raised portions and recessed portions and having the first surface tension.

7. The method of claim 5, wherein the curable conductive fluid does not adhere to the raised portions of the substrate surface and collects in the recessed portions.

8. The method of claim 5, wherein the curable conductive fluid is an ink.

9. The method of claim 5, wherein the curable conductive fluid is water based.

10. The method of claim 5, wherein the curable conductive fluid contains a metal.

11. The method of claim 5, wherein the curable conductive fluid flows into the recessed portions due to gravity.

12. The method of claim 1, wherein the conductive material added to the surface of the substrate covers both the raised portions and recessed portions of the surface of the substrate, and manipulating the surface of the substrate to provide the conductive material only in the recessed portions comprises removing the raised portions of the surface of the substrate.

13. The method of claim 12, wherein the substrate further comprises a layer of curable material at the substrate surface, the surface of the curable material comprising the pattern of raised portions and recessed portions.

14. The method of claim 12, wherein the conductive material in the recessed portions of the surface of the substrate is not disturbed when the raised portions of the surface of the substrate are removed.

15. The method of claim 12, wherein the raised portions of the surface of the substrate are removed by sanding.

16. The method of claim 12, wherein the raised portions of the surface of the substrate are removed by scraping.

17. The method of claim 12, wherein the raised portions of the surface of the substrate are removed by brushing.

18. The method of claim 12, wherein the raised portions of the surface of the substrate are removed by laser ablation.

19. The method of claim 12, wherein the conductive material is a metal.

20. The method of claim 19, wherein the metal is silver.

21. The method of claim 1, further comprising coating a masking material onto the raised portions of the substrate surface prior to adding the conductive material to the surface of the substrate, and wherein manipulating the surface of the substrate comprises removing the conductive material from the masking material on the raised portions of the surface of the substrate.

22. The method of claim 21, wherein the substrate further comprises a layer of curable material at the substrate surface, the surface of the curable material comprising the pattern of raised portions and recessed portions.

23. The method of claim 21, wherein the masking material is coated onto the raised portions of the substrate surface by printing.

24. The method of claim 21, wherein the masking material is a radiation curable silicone.

25. The method of claim 21, wherein the masking material is a microcrystalline wax.

26. The method of claim 21, wherein the conductive material is a metal.

27. The method of claim 21, wherein the conductive material is removed from the masking material on the raised portions of the surface of the substrate by nipping a second substrate against the surface of the substrate.

28. The method of claim 27, wherein the pattern of conductive material on the second substrate forms a circuit.
